(19) United States
(12) Patent Application Publication
(10) Pub. No.: US 2009/0137088 A1
(43) Pub. Date: May 28, 2009

(54) JFET Having a Step Channel Doping Profile and Method of Fabrication

(75) Inventors: Sachin R. Sonkusale, Los Gatos, CA (US); Weimin Zhang, Campbell, CA (US); Ashok K. Kapoor, Palo Alto, CA (US)

Correspondence Address: BAKER BOTTS L.L.P., 2001 ROSS AVENUE, SUITE 600, DALLAS, TX, 75201-2980, US

(73) Assignee: DSM Solutions, Inc., Los Gatos, CA (US)

(21) Appl. No.: 12/362,920

(22) Filed: Jan. 30, 2009

Related U.S. Application Data
(62) Division of application No. 11/744,113, filed on May 3, 2007.

(51) Int. Cl. H01L 21/337

(52) U.S. Cl. 438/194; 257/E21.445

(57) ABSTRACT

A junction field effect transistor comprises a semiconductor substrate, a source region formed in the substrate, a drain region formed in the substrate and spaced apart from the source region, and a gate region formed in the substrate. The transistor further comprises a first channel region formed in the substrate and spaced apart from the gate region, and a second channel region formed in the substrate and between the first channel region and the gate region. The second channel region has a higher concentration of doped impurities than the first channel region.

### CROSS-REFERENCE TO RELATED APPLICATION

This application is a divisional of U.S. application Ser. No. 11/744,113 filed May 3, 2007 and entitled “A JFET Having a Step Channel Doping Profile and Method of Fabrication”.

### TECHNICAL FIELD OF THE INVENTION

This invention relates in general to semiconductor devices, and more particularly to a junction field effect transistor having a step channel doping profile.

### BACKGROUND OF THE INVENTION

Prior junction field effect transistors use a single channel region to conduct current between the source and drain regions. This single channel region comprises a relatively uniform concentration of doped impurities. As a result, the performance of the transistor is not optimal during an ON-state and/or OFF-state of operation.

### SUMMARY OF THE INVENTION

In accordance with the present invention, the disadvantages and problems associated with prior junction field effect transistors have been substantially reduced or eliminated.

In accordance with one embodiment of the present invention, a junction field effect transistor comprises a semiconductor substrate. A source region, drain region, and gate region are formed in the substrate. The transistor further comprises a first channel region formed in the substrate and spaced apart from the gate region, and a second channel region formed in the substrate and between the first channel region and the gate region. The second channel region has a higher concentration of doped impurities than the first channel region.

Another embodiment of the present invention is a method for forming a junction field effect transistor. The method comprises forming a first channel region in a semiconductor substrate, and forming a second channel region in the substrate. The second channel region has a higher concentration of doped impurities than the first channel region. The method continues by forming a source region in the substrate, forming a drain region in the substrate spaced apart from the source region, and forming a gate region abutting the second channel region.

The following technical advantages may be achieved by some, none, or all of the embodiments of the present invention.

A particular advantage of the junction field effect transistor is that the relative doping concentrations of first and second channel regions results in a higher ON-state current to OFF-state current ratio than if the doping concentrations are uniform throughout the first and second channel regions. This is an advantage over prior transistor devices having a single channel with a uniform doping concentration throughout it. In particular, by using a step profile for the doping concentrations of the first and second channel regions, and by providing a smaller width for the channel region having the higher doping concentration than the width of the other channel region, the junction field effect transistor exhibits the same or an increased ON-state current and a reduced OFF-state current than prior transistors.

These and other advantages, features, and objects of the present invention will be more readily understood in view of the following detailed description, drawings, and claims.

### BRIEF DESCRIPTION OF THE DRAWINGS

For a more complete understanding of the present invention and its advantages, reference is now made to the following descriptions, taken in conjunction with the accompanying drawings, in which:

FIG. 1 illustrates a junction field effect transistor according to the present invention;

FIG. 2 is one embodiment of a chart illustrating the performance of the transistor of FIG. 1; and

FIGS. 3-13 illustrate one embodiment of a method for fabricating a transistor according to the present invention.

### DETAILED DESCRIPTION OF THE INVENTION

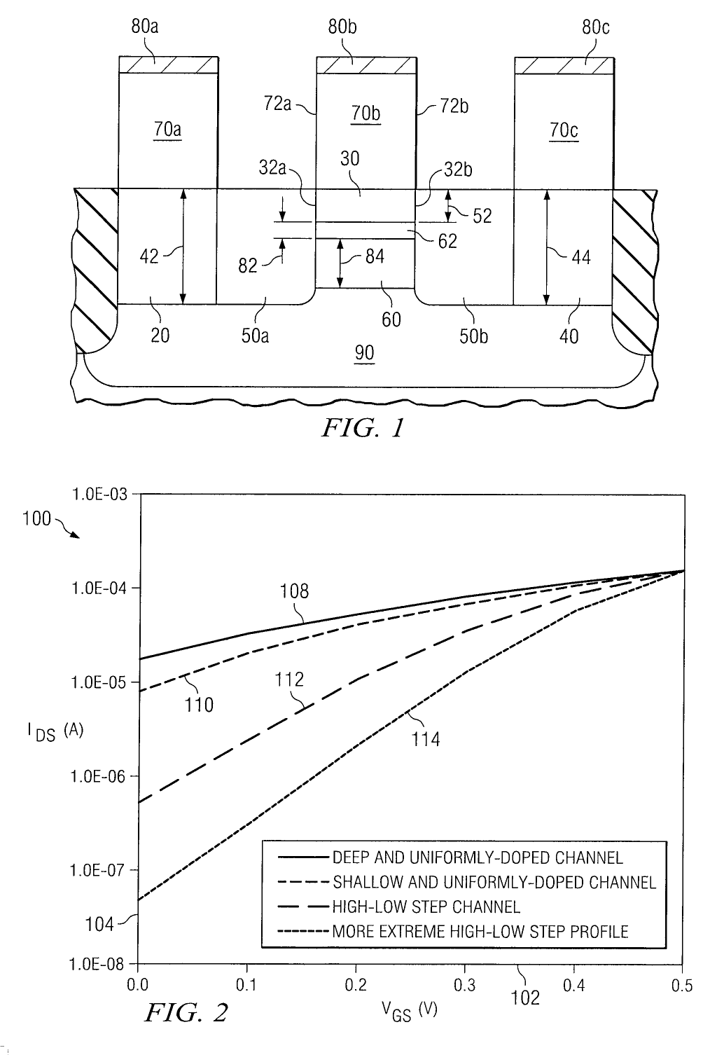

FIG. 1 illustrates a semiconductor device 10 according to a particular embodiment of the present invention. As shown in FIG. 1, semiconductor device 10 includes a source region 20, a gate region 30, a drain region 40, link regions 50a-b, a first channel region 60, a second channel region 62, polysilicon regions 70a-c, contacts 80a-c, and a substrate 90. These regions are not necessarily drawn to scale. Semiconductor device 10 comprises a junction field effect transistor (JFET). When appropriate voltages are applied to contacts 80 of semiconductor device 10, a current flows through channel regions 60 and 62 between source region 20 and drain region 40. By providing distinct channel regions 60 and 62, as described in greater detail below, semiconductor device 10 exhibits enhanced performance characteristics in an OFF-state and/or an ON-state of operation.

Substrate 90 represents bulk semiconductor material to which dopants can be added to form various conductivity regions (e.g., source region 20, gate region 30, drain region 40, and channel regions 60 and 62). Substrate 90 may be formed of any suitable semiconductor material, such as materials from Group III and Group V of the periodic table. In particular embodiments, substrate 90 is formed of single-crystal silicon. Substrate 90 may have a particular conductivity type, such as p-type or n-type. In particular embodiments, semiconductor device 10 may represent a portion of a substrate 90 that is shared by a plurality of different semiconductor devices (not illustrated in FIG. 1).

Channel regions 60 and 62 comprise distinct regions formed in substrate 90. Channel region 62 abuts gate region 30 and channel region 60 is separated from the gate region 30 by channel region 62. Together, channel regions 60 and 62 provide a path to conduct current between source region 20 and drain region 40 through link regions 50a and 50b. Channels 60 and 62 are formed by the addition of a first type of dopant to substrate 90. For example, the first type of dopant may represent particles of n-type doping material such as antimony, arsenic, phosphorous, or any other appropriate n-type dopant. Alternatively, the first type of dopant may represent particles of p-type doping material such as boron, gallium, indium, or any other suitable p-type dopant. Where the channels 60 and 62 are doped with n-type impurities, electrons flow from the source region 20 to the drain region 40 to create a current when an appropriate voltage is applied to device 10. Where channels 60 and 62 are doped with p-type impurities, holes flow from the source region 20 to the drain region 40 to create a current when an appropriate voltage is applied to device 10.

Channel region 62 has a higher concentration of doped impurities than channel region 60. For example, channel region 62 has a concentration of doped impurities that is between one-hundred and twenty-thousand times greater than channel region 60. In addition, the width 82 of channel region 62 is smaller than the width 84 of channel region 60. For example, width 82 is between two and twenty times smaller than width 84 of channel region 60. In a particular embodiment, width 82 of channel region 62 is five nanometers and the width 84 of channel 60 is thirty nanometers; the concentration of doping impurities in channel region 62 is 2E+19 cm⁻³; and the concentration of doping impurities in channel region 60 is 1E+15 cm⁻³. In another embodiment, width 82 of channel region 62 is ten nanometers and width 84 of channel 60 is twenty-eight nanometers; the concentration of doping impurities in channel region 62 is 8E+18 cm⁻³; and the concentration of doping impurities in channel region 60 is 1E+17 cm⁻³. Although particular parameters for channel regions 60 and 62 have been set forth above, device 10 can be constructed using any suitable parameters in order to optimize particular performance characteristics, such as operating current and voltage, without departing from the scope of the present invention. Other characteristics that may be considered to establish relative widths and doping concentrations include without limitation leakage current, size and shape of depletion regions, and so forth.

A particular advantage of device 10 is that the relative doping concentrations of channel region 62 and channel region 60 results in a higher ON-state current to OFF-state current ratio than if the doping concentrations are substantially uniform throughout the channel regions 62 and 60. This is an advantage over prior transistor devices having a single channel with a substantially uniform doping concentration throughout it. The ON-state current of device 10 is primarily controlled by the doping concentration in channel region 62, which is many times higher than that of channel region 60. The OFF-state current of device 10 is primarily controlled by the ratio of width 82 of channel region 62 to width 84 of channel region 60. By using a step profile for the doping concentrations of channel regions 62 and 60 (e.g., high concentration for channel region 62 and lower concentration for channel region 60) and by providing a smaller width 82 of channel region 62 than width 84 of channel region 60, device 10 exhibits the same or an increased ON-state current and a reduced OFF-state current than prior transistors.

Despite the relative doping concentrations of channels 60 and 62, the combined total carrier concentration of channels 60 and 62 can be maintained such that device 10 operates in an enhancement mode, with a positive current flowing between drain region 40 and source region 20 when a positive voltage differential is applied between source region 20 and gate region 30. In particular, the combined total carrier concentrations of channels 60 and 62 is lower than source region 20, drain region 40, and link regions 50a and 50b.

In particular embodiments, channel regions 60 and 62 are formed by epitaxial growth of silicon or alloys that include silicon, carbon, and/or germanium. In this regard, the doping concentration gradient between channel regions 60 and 62 can be precisely controlled. The dimensions and/or boundary of channel regions 60 and 62 may also be precisely controlled. In other embodiments, impurities can be ion implanted or diffused in substrate 90 to form channel regions 60 and 62 with the appropriate doping concentration profiles.

Furthermore, in particular embodiments, one or more boundaries of the channel regions 60 and 62 may be substantially aligned with an adjoining boundary of gate region 30. For example, as shown in FIG. 1, a surface of channel 62 may align with a surface of gate region 30. By limiting the amount that channel 62 extends beyond gate region 30 at the boundary between these two regions, particular embodiments of semiconductor device 10 may provide further reductions in the parasitic capacitance experienced by semiconductor device 10 during operation.

Source region 20 and drain region 40 each comprise regions of substrate 90 formed by the addition of the first type of dopant to substrate 90. Thus, for an n-channel device 10, source region 20 and drain region 40 are doped with n-type impurities. For a p-channel device 10, source region 20 and drain region 40 are doped with p-type impurities. In particular embodiments, source region 20 and drain region 40 have a doping concentration higher than 5E+19 cm⁻³.

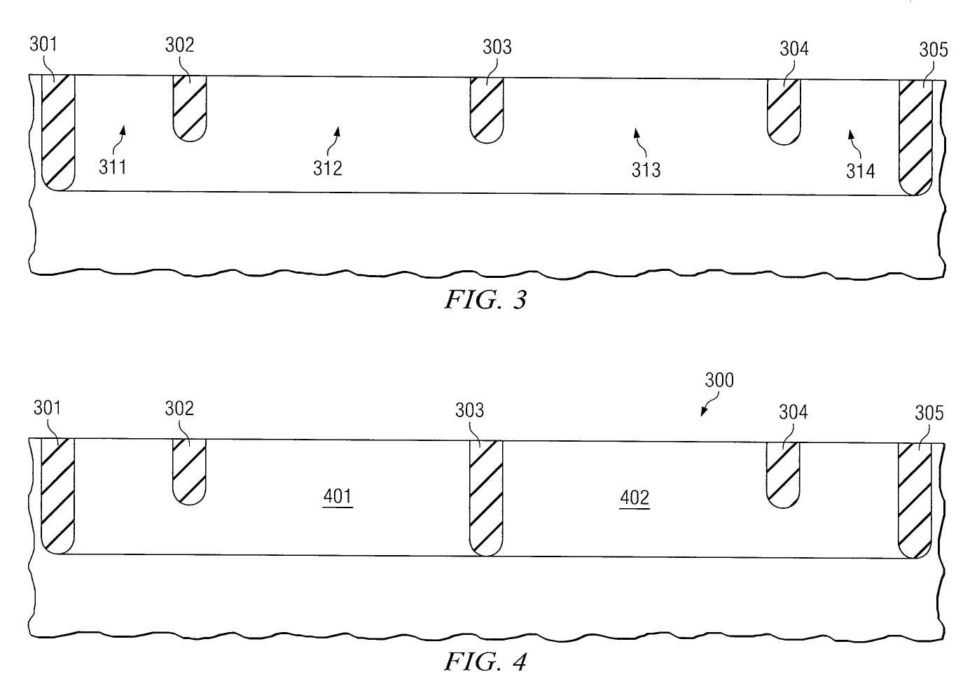

In particular embodiments, source region 20 and drain region 40 are formed by the diffusion of dopants through corresponding polysilicon regions 70a and 70c, respectively, as discussed in further detail below with respect to FIGS. 3-13. Consequently, in such embodiments, the boundaries and/or dimensions of source region 20 and drain region 40 may be precisely controlled. As a result, in particular embodiments, the depth of source region 20 (as indicated by arrow 42) is less than one-hundred nanometers (nm), and the depth of drain region 40 (as indicated by arrow 44) is also less than one-hundred nm. In certain embodiments, the depths of source region 20 and/or drain region 40 are between twenty and fifty nm. Because of the reduced size of source region 20 and drain region 40, particular embodiments of semiconductor device 10 may experience less parasitic capacitance during operation, thereby allowing semiconductor device 10 to function with a lower operating voltage.

Link regions 50a and 50b comprise regions of substrate 90 formed by doping substrate 90 with n-type or p-type impurities, as appropriate. In particular embodiments, link regions 50a and 50b are doped using a different technique from that used to dope source region 20 and drain region 40. Because link regions 50a and 50b are of the same conductivity type as source region 20 and drain region 40, however, the boundary between source region 20 and link region 50a and the boundary between drain region 40 and link region 50b may be undetectable once the relevant regions have been formed. For example, in particular embodiments, source region 20 and drain region 40 are formed by diffusing dopants through polysilicon regions 70a and 70c, respectively. Ion implantation is then used to add dopants to appropriate regions of substrate 90, thereby forming link regions 50a and 50b. Because the doping concentrations for these regions are similar or identical, the boundary between source region 20 and link region 50a and the boundary between drain region 40 and link region 50b are substantially undetectable after semiconductor device 10 has been formed.

Gate region 30 is formed by doping substrate 90 with a second type of dopant. As a result, gate region 30 has a second conductivity type. Thus, for an n-channel device 10, gate region 30 is doped with p-type impurities. For a p-channel device 10, gate region 30 is doped with n-type impurities. In particular embodiments, gate region 30 is doped with the second type of dopant to a concentration higher than 3E+19 cm⁻³. As described further below, when a voltage is applied to gate region 30, the applied voltage alters the conductivity of the neighboring channel regions 60 and 62, thereby facilitating or impeding the flow of current between source region 20 and drain region 40. Although FIG. 1 illustrates an embodiment of semiconductor device 10 that includes only a single gate region 30, alternative embodiments may include multiple gate regions 30.

In contrast to metal-oxide-semiconductor field-effect transistors (MOSFETs), semiconductor device 10 does not include any oxide layer covering the area in which gate region 30, source region 20, or drain region 40 are to be formed. As a result, gate region 30 may, in particular embodiments, be formed by the diffusion of dopants through a corresponding polysilicon region 70b, as discussed in further detail below with respect to FIGS. 3-13. Consequently, in such embodiments, the boundaries and/or dimensions of gate region 30 may be precisely controlled. As a result, in particular embodiments, the depth of gate region 30 (as shown by arrow 52) may be limited to less than fifty nm. In certain embodiments, the depth of gate region 30 may be between ten and twenty nm.

Additionally, as a result of gate region 30 being formed by the diffusion of dopants through polysilicon region 70b, gate region 30 may be precisely aligned with polysilicon region 70b. More specifically, one or more boundaries of gate region 30 may be substantially aligned with one or more surfaces of the polysilicon region 70b. For example, in particular embodiments, a first boundary 32a of gate region 30 may be aligned with a first boundary 72a of polysilicon region 70b to within ten nm, while a second boundary 32b of gate region 30 may be aligned with a second boundary 72b of polysilicon region 70b to within ten nm. By limiting the amount of gate region 30 that extends beyond the surfaces 72 of polysilicon region 70b, particular embodiments of semiconductor device 10 may provide further reductions in the parasitic capacitance experienced by semiconductor device 10 during operation.

Polysilicon regions 70a-c comprise polysilicon structures that provide an ohmic connection between contacts 80a-c and source region 20, gate region 30, and drain region 40, respectively. In particular embodiments, polysilicon regions 70 may connect pins of an integrated circuit package to the various regions of semiconductor device 10. Furthermore, as described further below, with respect to FIGS. 3-13, in particular embodiments, source region 20, drain region 40, and gate region 30 are formed by dopants that are diffused through polysilicon regions 70. As a result, in particular embodiments, polysilicon regions 70 may themselves comprise doped material, even after any appropriate diffusion of dopants into the various regions of substrate 90 has occurred.

Additionally, in particular embodiments, polysilicon regions 70 may be coplanar. Moreover, in particular embodiments, contacts 80 may additionally or alternatively be coplanar so that particular surfaces of all contacts 80 have the same height. Coplanar polysilicon regions 70 and/or contacts 80 may simplify the manufacturing and packaging of semiconductor device 10.

In operation, channels 60 and 62 provide a voltage-controlled conductivity path between source region 20 and drain region 40 through link regions 50. More specifically, a voltage differential between gate region 30 and source region 20 (referred to herein as V_{GS}) controls channels 60 and 62 by increasing or decreasing a width of a depletion region formed within channel regions 60 and 62. The depletion region defines an area within channel regions 60 and 62 in which the recombination of holes and electrons has depleted semiconductor device 10 of charge carriers. Because the depletion region lacks charge carriers, it will impede the flow of current between source region 20 and drain region 40. Moreover, as the depletion region expands or recedes, the portion of channels 60 and 62 through which current can flow grows or shrinks, respectively. As a result, the conductivity of channels 60 and 62 increases and decreases as V_{GS} changes, and semiconductor device 10 may operate as a voltage-controlled current regulator.

Furthermore, in particular embodiments, semiconductor device 10 comprises an enhancement mode device. Thus, when V_{GS}<0, the depletion region pinches off channels 60 and 62 preventing current from flowing between source region 20 and drain region 40. When V_{GS}>0, the depletion region recedes to a point that a current flows between source region 20 and drain region 40 through link regions 50 and channel regions 60 and 62 when a positive voltage differential is applied between source region 20 and drain region 40 (referred to herein as V_{DS}).

Overall, in particular embodiments, the dimensions of channel regions 60 and 62, gate region 30, source region 20, and/or drain region 40 may reduce the parasitic capacitances created within semiconductor device 10 and may, as a result, allow semiconductor device 10 to operate with reduced drive current. As a result, one or more semiconductors can be combined onto a microchip to form a memory device, processor, or other appropriate electronic device that is capable of functioning with a reduced operational voltage. For example, in particular embodiments of semiconductor device 10, channels 60 and 62 may conduct current between source region 20 and drain region 40 with a V_{GS} of 0.5V or less. Consequently, electronic devices that include semiconductor device 10 may be capable of operating at higher speed and with lower power consumption than conventional semiconductor devices.

FIG. 2 is one embodiment of a chart 100 illustrating the performance of device 10 under various constraints. Chart 100 has an x-axis 102 denoting the voltage (V_{GS}) applied to device 10, and a y-axis 104 denoting the current (I_{DS}) that flows between source region 20 and drain region 40 when the corresponding voltage is applied. Graph 108 illustrates the performance characteristics of a prior transistor having only a deep single channel with a substantially uniform doping concentration throughout it. Graph 110 illustrates the performance characteristics of a prior transistor having only a shallow single channel with a substantially uniform doping concentration throughout it. Graph 112 illustrates the performance characteristics of device 10 in an embodiment where: width 82 of channel region 62 is ten nanometers, and width 84 of channel region 60 is twenty-eight nanometers; the concentration of doping impurities in channel region 62 is 8E+18 cm⁻³; and the concentration of doping impurities in channel region 60 is 1E+17 cm⁻³. Graph 114 illustrates the performance characteristics of device 10 in an embodiment where: width 82 of channel region 62 is five nanometers, and width 84 of channel region 60 is thirty nanometers; the concentration of doping impurities in channel region 62 is 2E+19 cm⁻³; and the concentration of doping impurities in channel region 60 is 1E+15 cm⁻³. As illustrated by chart 100, device 10 having channel regions 60 and 62 has the same or higher ON-state current and a lower OFF-state current than prior transistors having only a single channel. Moreover, by increasing the doping concentration of channel region 62 in relation to channel region 60, and by reducing the width 82 of channel region 62 in relation to width 84 of channel region 60, as illustrated by graph 114, the OFF-state current of device 10 can be reduced even further. Although particular parameters for channel regions 60 and 62 have been set forth above, device 10 can be constructed using any suitable parameters in order to optimize particular performance characteristics without departing from the scope of the present invention.

FIG. 3 shows the cross sectional view of a semiconductor substrate after the preliminary steps during the fabrication have been completed to achieve the isolation of the various regions where active devices will be subsequently formed. The various elements of the semiconductor device described in FIGS. 3-13 are not necessarily drawn to scale. Structure 301-305 represent so-called Shallow Trench Isolation (STI) structures that are filled with insulating material, such as silicon dioxide and/or nitride, and formed to define the active areas 312 and 313. Regions 311 and 314 are used for forming the JFET's back-gate contacts. The details of the process for the formation of these structures, regions, and/or contacts are known to those skilled in the art. The particular manufacturing steps—including growth, oxidation, etching, diffusion and/or deposition of various layers of appropriate materials—for the formation of the JFET device(s) are also depicted in the subsequent steps detailed with respect to FIGS. 4-13. For example, an n-type channel JFET can be formed in region 312 and a p-type channel JFET can be formed in region 313. In this way, a complementary JFET electronic circuit, isolated from each other via the appropriate p-type and n-type well structures, can be formed in the same semiconductor substrate.

FIG. 4 shows the formation of p-wells and n-wells by doping the active regions with appropriate impurities in regions 401 and 402, respectively. These well regions provide isolation from substrate 90 for the JFETs. For the n-wells in region 402, phosphorous and/or arsenic atoms are implanted. The doping level of the implant varies between 1E+11 atoms/cm² to 1E+14 atoms/cm². The energy of implantation varies between 10 KeV and 400 KeV. For the p-wells in region 401, boron is introduced by ion implantation with a dose varying between 1E+11 atoms/cm² and 1E+14 atoms/cm². The energy of implantation varies between 10 KeV and 400 KeV. Multiple implants may be used to achieve the desired impurity doping profile. In order to selectively implant regions with n-type and p-type impurities, implants are done using photoresist masks to shield the region not designed to receive the implant. Additional implants of boron may be provided under the isolation regions 301-305 to increase the doping in the region underneath the oxide and prevent any leakage between the adjoining wells. The wafers are heat-treated to achieve the desired impurity doping profile. In other embodiments, the various regions of the JFETs can be formed in the semiconductor substrate without using n-wells or p-wells, as illustrated in FIG. 1. In these embodiments, the step of doping the semiconductor substrate to form the well regions can be omitted. Any other suitable modifications to the fabrication process are also contemplated.

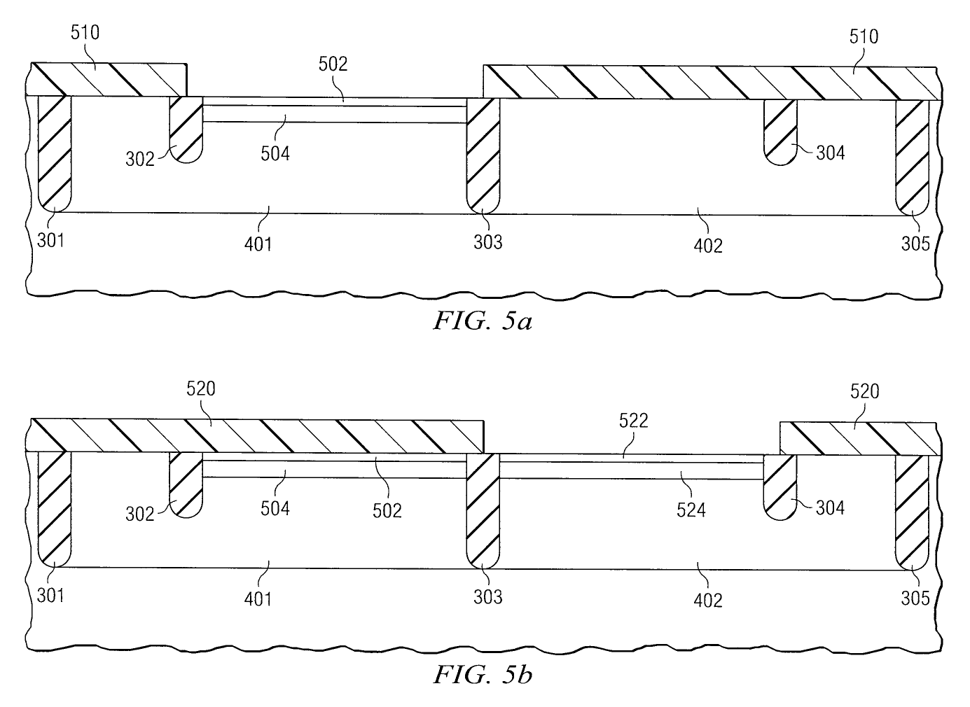

FIGS. 5a and 5b show the formation of channel regions 502 and 504 for the nJFET and 522 and 524 for the pJFET, respectively. In one embodiment, the channel regions may be formed by selective implantation using photoresist masks. For the nJFET, the channel regions are formed using an n-type dopant such as arsenic, phosphorous, or antimony with an implant energy between 1 and 100 KeV. Also shown in FIG. 5a is the photoresist 510 covering the regions where the n-channel implants are to be blocked. Referring to FIG. 5b, channel regions 522 and 524 of the pJFET are implanted with p-type impurities such as boron, indium or thallium with an implant energy between 1 and 100 KeV. In an alternative embodiment of the invention, the channel regions are formed by plasma immersion doping. Alternately, the channel regions are formed by epitaxial growth using, for example, silicon, silicon—germanium binary alloys, or silicon—germanium—carbon tertiary alloys. Other embodiments include variations in the formation of epitaxial regions by selective epitaxial growth of channel regions for n-channel and p-channel, as well as a single deposition of the channel regions for both nJFET and pJFET, followed by selective doping. Yet another embodiment of the invention covers the instance in which the channel regions are doped during deposition by methods such as atomic layer epitaxy. Other suitable techniques for forming channel regions are contemplated as well.

For the nJFET, channel region 504 is formed prior to channel region 502. Channel regions 502 and 504 correlate to channel regions 62 and 60 of FIG. 1, respectively, if semiconductor device 10 is an nJFET. For the pJFET, channel region 524 is formed prior to channel region 522. Channel regions 522 and 524 correlate to channel regions 62 and 60 of FIG. 1, respectively, if semiconductor device 10 is a pJFET. As described above with reference to channel regions 62 and 60 of FIG. 1, the implant dose of channel region 502 is higher than the implant dose of channel region 504, and the implant dose of channel region 522 is higher than the implant dose of channel region 524. Also as described above with reference to channel regions 62 and 60 of FIG. 1, the width of channel region 502 is smaller than that of channel region 504, and the width of channel region 522 is smaller than that of channel region 524.

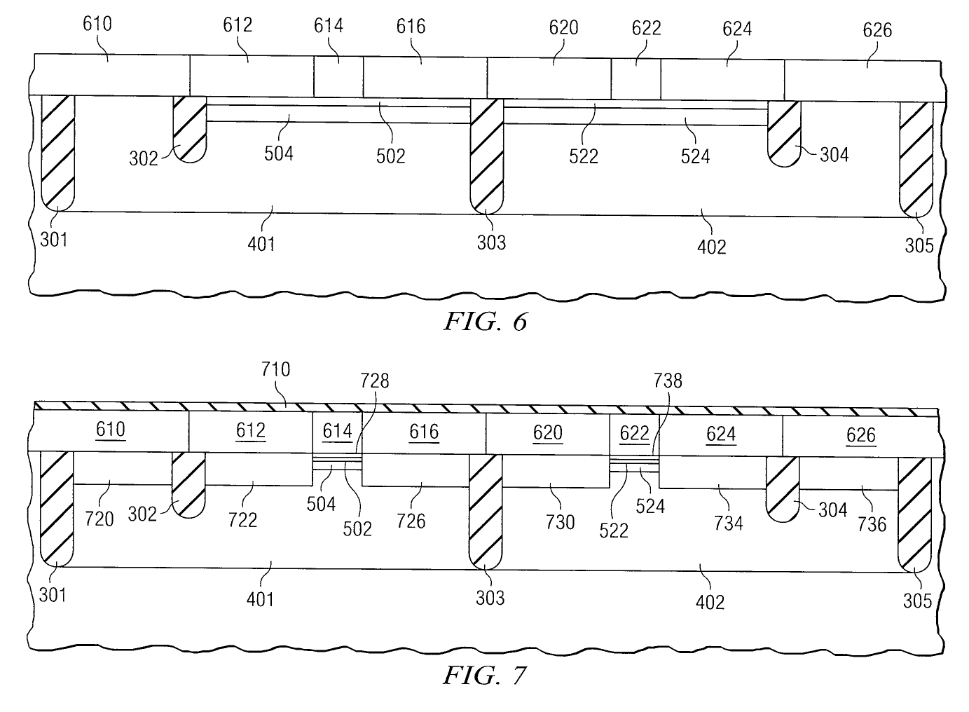

Next, a layer of polysilicon is deposited over the whole wafer, as shown in FIG. 6. The thickness of polysilicon deposited on the wafer varies between 100 Å and 10,000 Å. The polysilicon is selectively doped to form regions which will eventually become the source, drain, gate, and well contacts of the JFETs using photoresist as masks. The details of the photolithographic process are omitted here for the sake of brevity.

As shown in FIG. 6, the polysilicon region marked as 610 is doped with a heavy boron implant to a dose ranging between 1E+13 atoms/cm² and 1E+16 atoms/cm². It is designed to act as the contact for the well region of the n-JFET. Polysilicon region 614 is designed to act as the gate contact for the n-JFET. It is doped heavily p-type with the parameters similar to those of region 610. Polysilicon regions 612 and 616 are doped heavily with n-type dopants (phosphorous, arsenic, and antimony) to a dose ranging between 1E+13 atoms/cm² and 1E+16 atoms/cm², and are designed to act as the source and drain contacts of the nJFET, respectively.

The p-JFET is formed with polysilicon regions 620 and 624 acting as the source and drain contacts (p type), respectively, polysilicon region 622 as the gate contact (n type), and polysilicon region 626 as the contact to the well tap (n type). Polysilicon regions 620 and 624 are doped with a heavy concentration of boron atoms to a dose ranging between 1E+13 atoms/cm² and 1E+16 atoms/cm². Similarly, polysilicon regions 622 and 626 are doped heavily n-type.

In an alternative embodiment, a layer of oxide is deposited on top of the polysilicon layer before performing an ion implantation. The thickness of this layer varies between 20 Å and 500 Å. In another embodiment, layers of oxide and/or nitride are deposited on top of the polysilicon prior to ion implantation, with the thickness of the oxide and nitride films varying between 10 Å and 500 Å.

FIG. 7 shows the cross section of the silicon wafer with the polysilicon layer doped with impurities, and a protective layer 710 on top of the polysilicon layer. The polysilicon layer with impurities implanted in various regions is used as a source of indirect diffusion of those impurities into the silicon to form the source, drain, and gate junctions and ohmic connections to the well. Regions 722 and 726 are the source and drain regions of the nJFET which are diffused from polysilicon regions 612 and 616. The gate region, marked as 728, is diffused into the silicon from the p-doped polysilicon region 614. Region 720 is the p-type region (well tap) formed in the silicon by diffusion from the polysilicon region 610 and forms an ohmic contact to the p-well which contains the nJFET. Similarly, the pJFET is formed with region 730 as the source, region 734 as the drain, region 736 as the well contact, and region 738 as the gate of the pJFET. These regions contain impurities diffused from the polysilicon regions 620, 624, 626, and 622. In an alternative embodiment, multiple ion implants, varying the implant dose and energy, of n-type and p-type dopants in polysilicon are made to form the well contacts, source, drain, and gate regions.

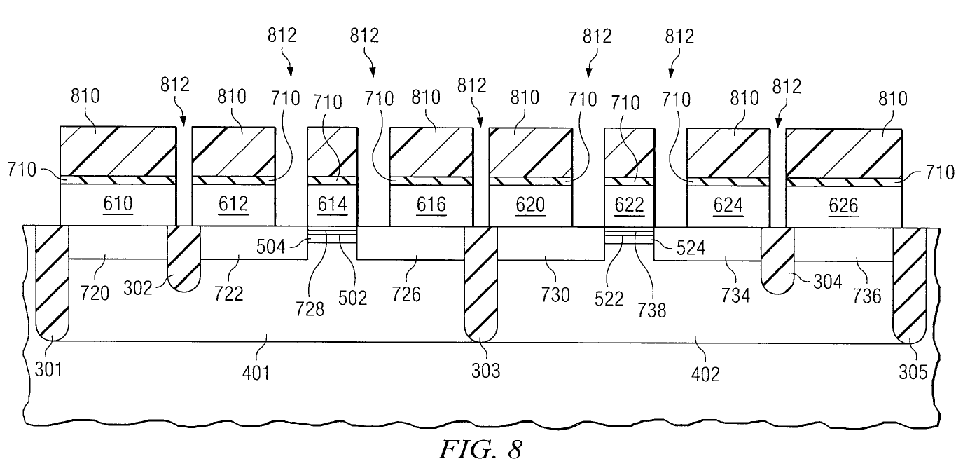

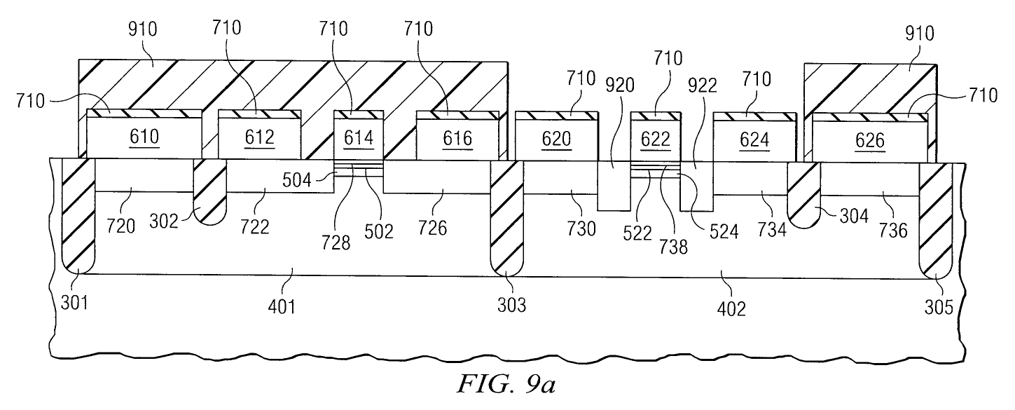

After diffusion of the various regions of the JFETs into the silicon, the contact patterning process takes place. Using an optical lithographic process, a layer of an anti-reflective coating, if needed, followed by a layer of photoresist are coated on the wafer. The thickness of these layers depends upon the selection of the photoresist, as is known to those skilled in the art. The photoresist layer is exposed and various terminals are delineated in the photoresist, marked as 810 in FIG. 8. Alternate embodiments of this invention includes other methods of patterning the photoresist, including imprint lithography and e-beam lithography. With the photoresist layer as the mask, the protective layer above the polysilicon is etched first. Next, the polysilicon layer is etched, with the grooves such as 812 reaching the bottom of the polysilicon layer. This step isolates the various terminals electrically. For patterning the photoresist, various processes such as but not limited to optical lithography, immersion lithography, imprint lithography, direct write e-beam lithography, x-ray lithography, or extreme ultraviolet lithography are used.

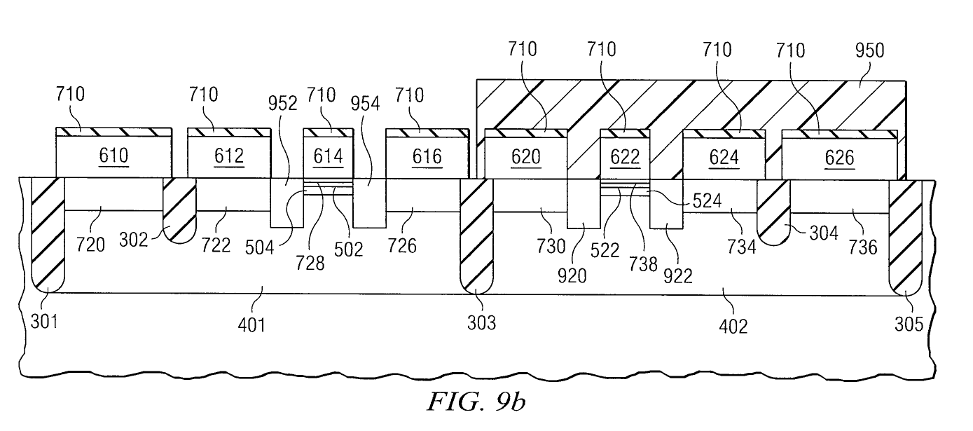

FIG. 9a is a cross section of the silicon wafer. After etching the polysilicon layer, the region between the heavily doped regions and the channel regions are doped to form a low resistivity path between the source and channel regions, and the drain and channel regions. They are referred to as link regions 920 and 922 respectively. FIG. 9a shows the formation of link regions 920 and 922 for a pJFET. The section of the wafer containing the nJFET is covered by photoresist 910 during this step while a suitable doping process such as but not limited to ion implantation or plasma immersion implantation is used to dope the link regions 920 and 922 of pJFET. The link regions are formed to a junction depth independent from that of the neighboring source and drain regions, and are designed to provide a very low resistivity connection between the source and the channel regions, and between the drain and the channel regions.

FIG. 9b is a cross section of the silicon wafer after doping additional link regions 952 and 954 between the channel regions and the drain, and between the channel regions and the source of the nJFET. Object 950 is the photoresist covering the regions where the implant is blocked, which contain the pJFET. Regions 952 and 954 in the silicon are the link regions formed by the implantation of n-type dopants. After ion implantation, the dopants are activated by a rapid thermal annealing process. An oxidation step, at temperatures ranging between 700 C and 950 C and for times ranging between 10 seconds and 20 minutes, is also performed to oxidize any regions of silicon that may have been damaged during etching.

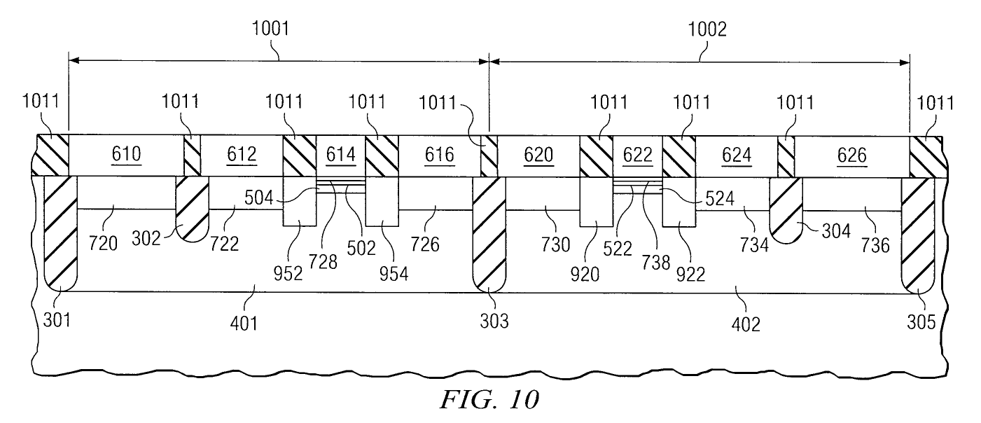

FIG. 10 shows the cross section of the wafer after the gap between the polysilicon blocks is filled with an insulating material 1011 such as silicon dioxide and then processed, using a method such as chemical-mechanical-polishing, to provide a nearly planar surface at the same level as the polysilicon layer. The technique of filling insulating material 1011 in between the polysilicon blocks in regions 1001 and 1002 by depositing silicon dioxide using chemical vapor deposition or plasma assisted chemical vapor deposition is one which is widely used in semiconductor manufacturing. One such process employs the deposition of oxide by a low temperature plasma-activated reaction between silane and oxygen in gaseous form. The protective layer 710 is removed to expose the bare polysilicon surface.

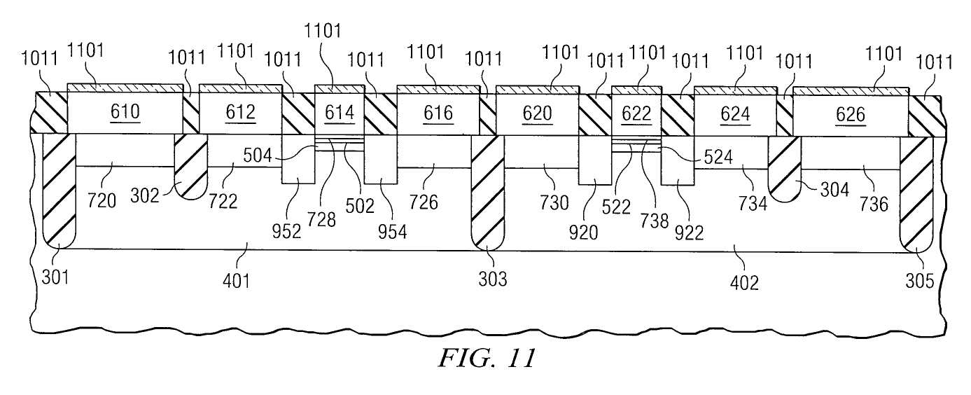

FIG. 11 is the cross section of the silicon wafer after formation of self aligned silicide on the exposed polysilicon surfaces. A layer of a metal such as nickel, cobalt, titanium, platinum, palladium, or other refractory metal is deposited on the polysilicon surface and annealed such that the exposed regions of polysilicon form a binary compound with the metal layer known as “metal suicides.” The metal silicide 1101 is a highly conductive substance. The preferred thickness of the deposited metal is between 50 Å and 1000 Å on an atomically clean surface of polysilicon. The wafers are heated in a rapid anneal furnace at temperatures between 200 C and 800 C for a time period between 10 seconds and 30 minutes to form silicides selectively where metal is in contact with a polysilicon layer. After the reaction between the metal layer and silicon has taken place, the excess metal is removed from the wafer by a chemical etching process which does not affect the silicide layer. Unreacted metal is selectively etched off using appropriate solvents, leaving only metal silicide 1101 over the exposed polysilicon regions. For titanium and cobalt, a mixture of hydrogen peroxide and ammonium hydroxide is used in a ratio of 1:0.1 to 1:10 as appropriate at room temperature, although temperatures above room temperatures can also be used. Thus, a self aligned layer of silicide is formed on polysilicon. FIG. 11 shows the cross section of the device after formation of silicide 1101 on the polysilicon regions. The polysilicon regions are also used as local interconnects, whereby regions of silicided n-type polysilicon and p-type polysilicon are used for making ohmic contacts.

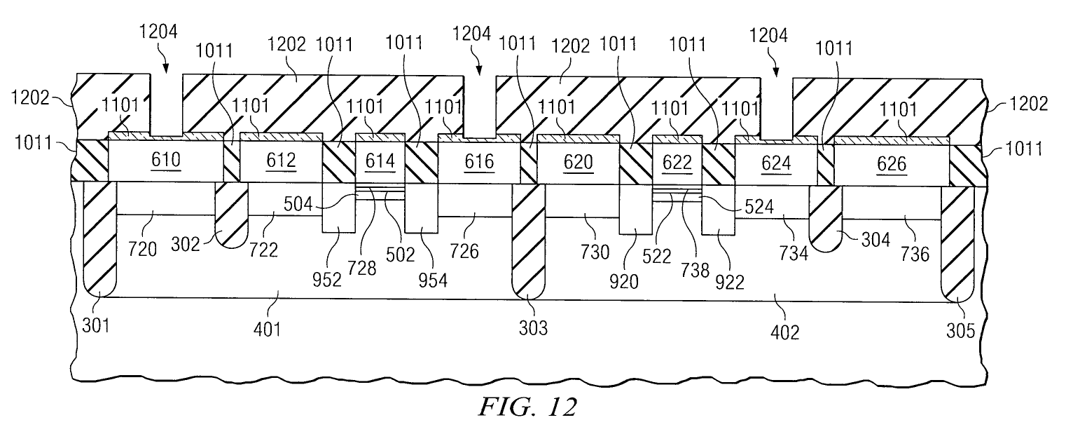

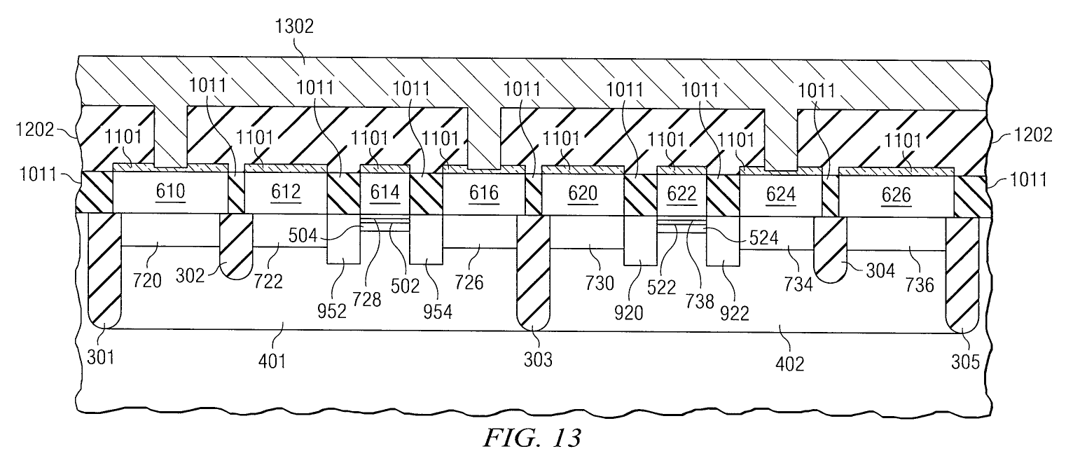

The next process step consists of depositing a dielectric (oxide) layer 1202, etching contact holes in the oxide layer, and forming contact holes for the source, drain, gate and well tap terminals, and continuing with the conventional metal interconnect formation process as practiced in the formation of semiconductor chips. For example, a cross section of the wafer after dielectric deposition and contact hole etch 1204 for the drain terminal is shown in FIG. 12. The associated metal deposition 1302 and etch is shown in FIG. 13. Additional fabrication (not shown) can be performed for the remaining terminals.

Although the present invention has been described in detail, it should be understood that various changes, substitutions and alterations can be made hereto without departing from the sphere and scope of the invention as defined by the appended claims.

What is claimed is:

1. A method for fabricating a junction field effect transistor, the method comprising:
forming a first channel region in a semiconductor substrate;
forming a second channel region in the substrate, wherein the second channel region has a higher concentration of doped impurities than the first channel region;
forming a gate region abutting the second channel region;
forming a source region in the substrate; and
forming a drain region in the substrate spaced apart from the source region.

2. The method of claim 1, wherein the second channel region has a smaller channel width than the first channel region.

3. The method of claim 1, wherein the first and second channel regions have an n-type conductivity.

4. The method of claim 1, wherein the first and second channel regions have a p-type conductivity.

5. The method of claim 1, wherein the different doping concentrations of the first channel region and the second channel region results in a higher on-state current to off-state current ratio than if the doping concentrations of the first and second channel regions are similar.

6. The method of claim 2, wherein the different widths of the first channel region and the second channel region results in a higher on-state current to off-state current ratio than if the widths of the first and second channel regions are similar.

7. The method of claim 1, wherein the second channel region has a concentration of doped impurities that is between one-hundred and twenty-thousand times greater than the first channel region.

8. The method of claim 1, wherein the gate region is formed by diffusing impurities from a gate electrode region overlaying the substrate.

9. The method of claim 1, wherein the source region is formed by diffusing impurities from a source electrode region overlaying the substrate.

10. The method of claim 1, wherein the drain region is formed by diffusing impurities from a drain electrode region overlaying the substrate.

11. The method of claim 1, further comprising forming a well region in the substrate, wherein the source region, drain region, gate region, and the first and second channel regions are formed in the well region.

12. The method of claim 1, further comprising forming a first link region and a second link region.

13. The method of claim 1, wherein the first channel is formed using epitaxial growth.

14. The method of claim 1, wherein the first channel is formed using diffusion.

15. The method of claim 1, wherein the first channel is formed using ion implantation.

16. A method for fabricating a junction field effect transistor, the method comprising:
implanting impurities of a first conductivity type in a substrate to form a well region;
implanting impurities of a second conductivity type in the well region using a first implant dosage to form a first channel region;
implanting impurities of the second conductivity type in the well region using a second implant dosage to form a second channel region, the second implant dosage being greater than the first implant dosage;
forming a gate region abutting the second channel region;
forming a source region in the substrate; and
forming a drain region in the substrate spaced apart from the source region.

17. The method of claim 16, wherein the second channel region has a smaller channel width than the first channel region.

18. The method of claim 16, wherein the first and second channel regions have an n-type conductivity.

19. The method of claim 16, wherein the first and second channel regions have a p-type conductivity.

20. The method of claim 16, wherein the different implant dosages of the first channel region and the second channel region results in a higher on-state current to off-state current ratio than if the implant dosages of the first and second channel regions are similar.

21. The method of claim 17, wherein the different widths of the first channel region and the second channel region results in a higher on-state current to off-state current ratio than if the widths of the first and second channel regions are similar.

22. A method for fabricating a junction field effect transistor, the method comprising:
implanting impurities of a first conductivity type in a substrate to form a first channel region;
implanting impurities of the first conductivity type in the substrate to form a second channel region, wherein the second channel region is formed abutting the first channel region;
forming a gate region abutting the second channel region, the gate region comprising a second conductivity type;
forming a source region in the substrate, the source region comprising the first conductivity type; and
forming a drain region in the substrate spaced apart from the source region, the drain region comprising the first conductivity type.

23. The method of claim 22, wherein the second channel region has a smaller channel width than the first channel region.

24. The method of claim 22, wherein the first and second channel regions have an n-type conductivity.

25. The method of claim 22, wherein the first and second channel regions have a p-type conductivity.

26. The method of claim 1, wherein the first and second channel regions have different doping concentrations for the impurities, which results in a higher on-state current to off-state current ratio than if the doping concentrations of the first and second channel regions are similar.

27. The method of claim 23, wherein the different widths of the first channel region and the second channel region results in a higher on-state current to off-state current ratio than if the widths of the first and second channel regions are similar.

28. The method of claim 22, further comprising forming a well region in the substrate, wherein the source region, drain region, gate region, and the first and second channel regions are formed in the well region, and the well region comprises the second conductivity type.
